(19) United States
(12) Patent Application Publication
(10) Pub. No.: US 2026/0122875 A1
(43) Pub. Date: Apr. 30, 2026

(54) FABRICATION METHOD FOR U-TRENCH

(71) Applicant: Shanghai Huali Integrated Circuit Corporation, Shanghai (CN)

(72) Inventor: Shiling Yang, Shanghai (CN)

(73) Assignee: Shanghai Huali Integrated Circuit Corporation, Shanghai (CN)

(21) Appl. No.: 19/235,713

(22) Filed: Jun. 12, 2025

(30) Foreign Application Priority Data
Oct. 31, 2024 (CN) 202411547779.9

(51) Int. Cl. H10B 12/00; H01L 21/02; H01L 21/027; H01L 21/033; H01L 21/308; H01L 21/311

(52) U.S. Cl. CPC H10B 12/053; H10P 14/69215; H10P 14/69433; H10P 50/692; H10P 50/695; H10P 50/73; H10P 76/2041; H10P 76/405; H10P 76/4085

(57) ABSTRACT

The present application discloses a fabrication method for a U-trench. A photoresist retained on field oxygen in an X-direction photolithography process of the U-trench will protect a hard mask on the field oxygen of a Y-direction opening in a non-U-trench area without causing the loss of the hard mask on the field oxygen of the Y-direction opening in the non-U-trench area. In a process of forming the U-trench by X-direction silicon etching, silicon at the X-direction opening at a non-overlapping position of an X-direction opening pattern and a Y-direction opening pattern is protected by a first silicon oxide layer of mask and a second silicon nitride layer of mask. When the mask on the field oxygen is removed, the first silicon oxide layer is removed after the second silicon nitride layer of mask is removed, which will not damage the SIN hard mask on the field oxygen.

### CROSS-REFERENCE TO RELATED APPLICATIONS

This application claims priority to Chinese patent application No. 202411547779.9, filed on Oct. 31, 2024, the disclosure of which is incorporated herein by reference in its entirety.

### TECHNICAL FIELD

The present application relates to a semiconductor fabrication technology, and in particular, to a fabrication method for a U-trench.

### BACKGROUND

A capacitor is the bottleneck of the development of a traditional DRAM (Dynamic Random Access Memory), and a semi-floating-gate transistor is a potential capacitor-free DRAM compatible with a standard logic process and is easier to miniaturize. The U-trench can isolate a semi-floating-gate N well, and forms a U-channel at a bottom thereof, which is beneficial for miniaturizing the device area compared to traditional profile channels. In addition, a polysilicon gate (poly gate) in the U-trench is used to store a charge, and a tunneling effect is employed to accelerate the writing of the charge.

In an existing method, in a semi-floating-gate process compatible with a storage array and a logic circuit, the U-trench is developed by opening an array area with array area photolithography (PH), then removing a pad SiN by dry etching and then sequentially depositing (dep) SIN/OX/SIN as a HM (hard mask). U-trench X PH/ET first opens SIN and OX on an upper layer of the mask of the X-direction opening and stops on SiN on a lower layer of the mask to form an X-direction opening HM pattern. On this basis, U-trench Y PH/ET opens SIN and STI OX on the mask remaining in the U-trench area and stops on a pad silicon oxide layer (OX), then opens the pad silicon oxide layer (OX) under the protection of the HM formed by the X PH/ET and the Y PH/ET, and etches a Si substrate to form the U-trench, wherein U-trench Y represents a Y direction of the U-trench, U-trench X represents an X direction of the U-trench, the U-trench Y is perpendicular to a length direction of active areas, and the U-trench X is parallel to the length direction of the active areas.

In the existing method, a number of times of U-trench X low-selectivity etching is firstly required to be performed without stopping interfaces, which is easily affected by the uniformity of a within-wafer (WIW) HM film thickness, and then U-trench Y low-selectivity etching is performed to remove a part of SiN on the lower layer and a part of the STI OX. A U-trench X area needs to retain the SIN when the U-trench Y low-selectivity etching is performed, which is to protect the semiconductor silicon substrate of the X-direction opening of the U-trench of the non-U-trench area, so as to avoid the loss of the AAs (active areas) the X-direction opening of the U-trench of the non-U-trench area. However, the loss of the STI HM of a U-trench Y opening area will be caused during the SIN RM. The U-trench Y high-selectivity etching is performed and stopped on the pad silicon oxide layer (OX). The U-trench Y high-selectivity etching will result in an STI OX profile taper, and the STI OX will be more difficult to pull back.

In the process of etching the U-trench by the existing method, it is necessary to take into account a U-trench X opening/a U-trench Y-opening/a process window of the U-trench area, so as to ensure that a U-trench X opening area has no damage, ensure that the STI HM of the U-trench Y opening area is not lost too much, and guarantee the profile standard of the U-trench.

### BRIEF SUMMARY

A technical problem to be solved by the present application is to provide a fabrication method for a U-trench, which can increase the process tolerance, enlarge a process window of the U-trench, have no damage on a SIN hard mask on field oxygens when a mask at an X-direction opening at a non-overlapping position of an X-direction opening pattern and a Y-direction opening pattern is removed, and ensure a profile standard of the U-trench.

In order to solve the technical problem mentioned above, the fabrication method for the U-trench provided by the present application includes the following steps:
S1. providing a semiconductor silicon substrate 100 provided with a plurality of X-direction field oxygens 101 and a shallow trench isolation 102, wherein
the semiconductor silicon substrate 100 comprises a first area 103 and a second area 104 separated by the shallow trench isolation 102;
in the first area 103, the semiconductor silicon substrate 100 is isolated by a plurality of X-direction field oxygens 101 into a plurality of X-direction first active areas 105, and the plurality of X-direction field oxygens 101 and the plurality of X-direction first active areas 105 are arranged in parallel; and
an X direction is a direction parallel to a length direction of the first active areas 105, and a Y direction is perpendicular to the X direction;
S2. opening the first area 103 to expose upper surfaces of the X-direction field oxygens 101 and upper surfaces of the first active areas 105 of the first area 103;
S3. depositing a hard mask layer 106 on the first area 103, wherein the hard mask layer 106 includes a first silicon oxide layer 106a of a mask, a second silicon nitride layer 106b of mask and a third silicon oxide layer 106c of mask that are sequentially overlapped from bottom to top;
S4. coating a first photoresist on the hard mask layer 106, and then performing Y-direction opening lithography to form a Y-direction opening pattern; then performing Y-direction oxide etching to remove the third silicon oxide layer 106c of mask of the Y direction opening, and stopping the Y-direction oxide etching on a top surface of the second silicon nitride layer 106b of mask; and then removing the first photoresist;
S5. coating a second photoresist 108 on a surface of the first area 103, and then define an X-direction opening pattern by lithography, wherein an X-direction opening corresponds to the corresponding first active area;
S6. according to the defined X-direction opening pattern, performing a first part of X-direction silicon nitride etching, such that the second silicon nitride layer 106b of mask at an overlapping position of the X-direction opening pattern and the Y-direction opening pattern is removed; and the first part of X-direction silicon nitride etching stopped on the top surface of the first silicon oxide layer 106a of mask of the X-direction opening, such that the X-direction opening at a non-overlapping position of the X-direction opening pattern and the Y-direction opening pattern is covered with the first silicon oxide layer 106a of mask, the second silicon nitride layer 106b of mask and the third silicon oxide layer 106c of mask;
S7. according to the defined X-direction opening pattern, performing a second part of X-direction oxide etching for at least one time, such that the first silicon oxide layer 106a of mask at the overlapping position of the X-direction opening pattern and the Y-direction opening pattern is removed; and the second part of X-direction oxide etching stopped on a top surface of the semiconductor silicon substrate 100, such that the X-direction opening at the non-overlapping position of the X-direction opening pattern and the Y-direction opening pattern is covered with the first silicon oxide layer 106a of mask and the second silicon nitride layer 106b of mask;
S8. according to the defined X-direction opening pattern, performing a third part of X-direction silicon etching, such that the U-trench is formed in the semiconductor silicon substrate at the overlapping position of the X-direction opening pattern and the Y-direction opening pattern;
S9. sequentially removing the second silicon nitride layer 106b of mask and the first silicon oxide layer 106a of mask covered by the X-direction opening at the non-overlapping position of the X-direction opening pattern and the Y-direction opening pattern; and
S10. performing a subsequent process.

Preferably, the X-direction field oxygens 101 are formed by using a shallow trench isolation process.

Preferably, in the step S1, a pad layer 109 is formed on an upper surface of the semiconductor silicon substrate 100; and the first active areas 105 are covered with the pad layer 109.

In the step S2, the pad layer 109 on the first area 103 is removed and the first area 103 is opened.

Preferably, the pad layer 109 is composed of a lower pad silicon oxide layer 110 and an upper silicon nitride layer;

in the step S2, the upper silicon nitride layer on the first active areas 105 of the first area 103 is removed and the lower pad silicon oxide layer 110 is retained, and the first area 103 is opened;

in the step S7, the second part of X-direction oxide etching is performed for at least one time according to the defined X-direction opening pattern, such that the first silicon oxide layer 106a of mask at the overlapping position of the X-direction opening pattern and the Y-direction opening pattern and the lower pad silicon oxide layer 110 are removed; and the second part of X-direction oxide etching is stopped on the top surface of the semiconductor silicon substrate 100, such that the X-direction opening at the non-overlapping position of the X-direction opening pattern and the Y-direction opening pattern is covered with the lower pad silicon oxide layer 110, the first silicon oxide layer 106a of mask and the second silicon nitride layer 106b of mask; and

in the step S9, the second silicon nitride layer 106b of mask, the first silicon oxide layer 106a of mask and the lower pad silicon oxide layer 110 covered by the X-direction opening at the non-overlapping position of the X-direction opening pattern and the Y-direction opening pattern are removed sequentially.

Preferably, in the step S4, the Y-direction oxide etching is high-selectivity etching with an OX/SIN selectivity of greater than 50:1.

Preferably, in the step S6, the first part of X-direction silicon nitride etching is high-selectivity etching with a SIN/OX selectivity of greater than 50:1.

In the step S7, the second part of X-direction oxide etching is low-selectivity etching with an OX/SIN selectivity of less than 5:1, and the upper surface of the semiconductor silicon substrate in the U-trench area is exposed.

Preferably, the U-trench is a semi-floating-gate trench of a semi-floating-gate transistor.

Preferably, the first area 103 is a formation area of a plurality of semi-floating-gate transistors; and

in the first area 103, the plurality of semi-floating-gate transistors are arranged to form a storage array.

Preferably, each of the first active area 105 is provided with a first conductive type well, and the first conductive type well is formed in a surface area of a second conductive type well; and

the U-trench passes through the first conductive type well, and a bottom surface of the U-trench enters the second conductive type well.

Preferably, the semi-floating-gate transistor is an N-type device, a first conductive type is N-type, and a second conductive type is P-type; or

the semi-floating-gate transistor is a P-type device, a first conductive type is P-type, and a second conductive type is N-type.

According to the fabrication method for the U-trench of the present application, process windows of the U-trench Y-direction opening hard mask etching, the U-trench X-direction opening hard mask etching and the U-trench area silicon etching do not affect each other, which increases the process tolerance. The second photoresist 108 retained on the field oxygens 103 in the X-direction lithography process of the U-trench will protect the hard mask (the first silicon oxide layer 106a, the second silicon nitride layer 106b of mask) on the field oxygens 103 of the Y-direction opening of the non-U-trench area without causing the loss of the hard mask on the field oxygens of the Y-direction opening of the non-U-trench area, which enlarges the process window of the U-trench. In a process of performing X-direction silicon etching (U-trench X SI ET) to form the U-trench in the semiconductor silicon substrate at the overlapping position of the X-direction opening pattern and the Y-direction opening pattern, silicon at the X-direction opening at the non-overlapping position of the X-direction opening pattern and the Y-direction opening pattern is protected by the first silicon oxide layer 106a of mask and the second silicon nitride layer 106b of mask. When the mask at the X-direction opening at the non-overlapping position of the X-direction opening pattern and the Y-direction opening pattern is removed, the first silicon oxide layer 106a is removed after the second silicon nitride layer 106b of mask is removed, which has no damage on the SIN hard mask on the field oxygens 103 and ensure the profile standard of the U-trench. In addition, the fabrication method for the U-trench requires less mask.

### BRIEF DESCRIPTION OF THE DRAWINGS

To more clearly illustrate the technical solution of the present application, figures used in the present application will be briefly introduced below. Obviously, the figures in the following description are only some embodiments of the present application, and other figures can be obtained from these figures for those of ordinary skill in the art, without the exercise of inventive effect.

FIG. 1 is a schematic diagram of a three-dimensional structure of a semiconductor silicon substrate when a first area is opened in a fabrication method for a U-trench according to an embodiment of the present application;

FIG. 2 is a schematic diagram of a three-dimensional structure after a hard mask layer is deposited in a fabrication method for a U-trench according to an embodiment of the present application;

FIG. 3 is a schematic diagram of a three-dimensional structure after Y direction oxide etching is performed in a fabrication method for a U-trench according to an embodiment of the present application;

FIG. 4 is a schematic diagram of a cross-sectional structure after Y-direction oxide etching is performed in a fabrication method for a U-trench according to an embodiment of the present application;

FIG. 5 is a schematic diagram of a cross-sectional structure after a first part of X direction silicon nitride etching is performed in a fabrication method for a U-trench according to an embodiment of the present application;

FIG. 6 is a schematic diagram of a cross-sectional structure after a second part of X direction oxide etching is performed in a fabrication method for a U-trench according to an embodiment of the present application;

FIG. 7 is a schematic diagram of a cross-sectional structure after a third part of X-direction silicon etching is performed in a fabrication method for a U-trench according to an embodiment of the present application; and

FIG. 8 is a schematic diagram of a three-dimensional structure after the hard mask at the non-overlapping position of the X-direction opening is removed in a fabrication method for a U-trench according to an embodiment of the present application.

### DESCRIPTION OF REFERENCE SYMBOLS IN THE FIGURES

100. semiconductor silicon substrate; 101. field oxygen; 102. STI; 3. first area; 104. second area; 105. first active area; 106. hard mask layer; 106a. first silicon oxide layer of mask; 106b. second silicon nitride layer of mask; 106c. third silicon oxide layer of mask; 108. second photoresist; 109. pad layer; and 110. pad silicon oxide layer.

### DETAILED DESCRIPTION OF THE DISCLOSURE

Technical solutions in the present application may be described clearly and completely below in conjunction with figures in the present application. Obviously, the described embodiments are only some of the embodiments of the present application, but not all of the embodiments. The scope of protection of the present application encompasses all other embodiments obtained by those of ordinary skill in the art based on the embodiments of the present application without the exercise of inventive effort.

### Embodiment 1

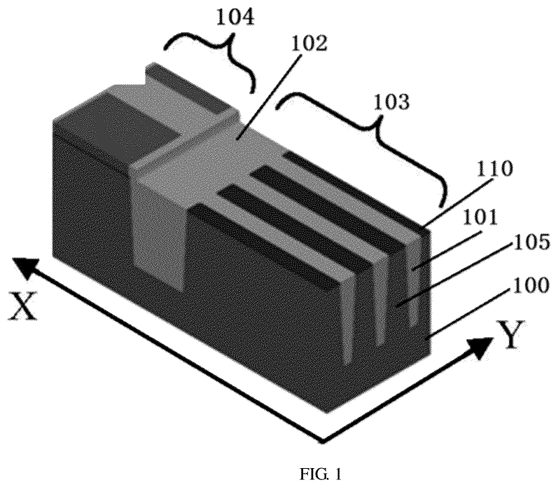

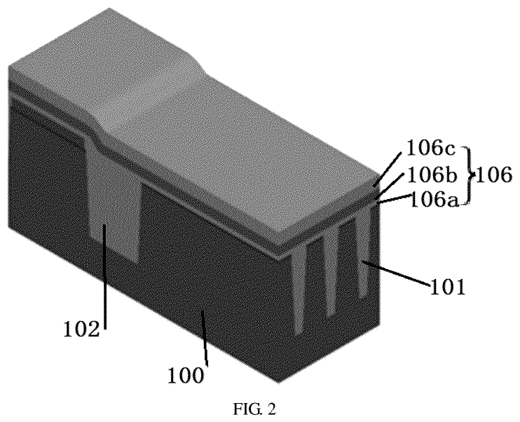

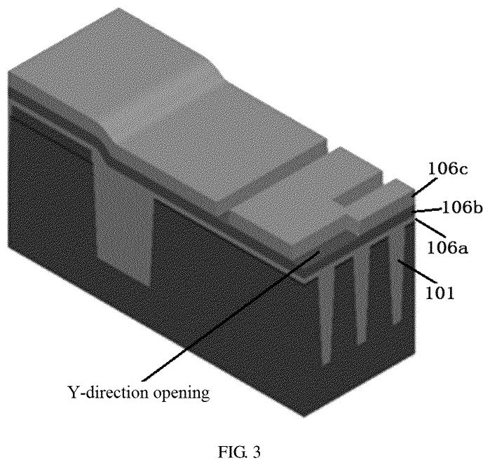

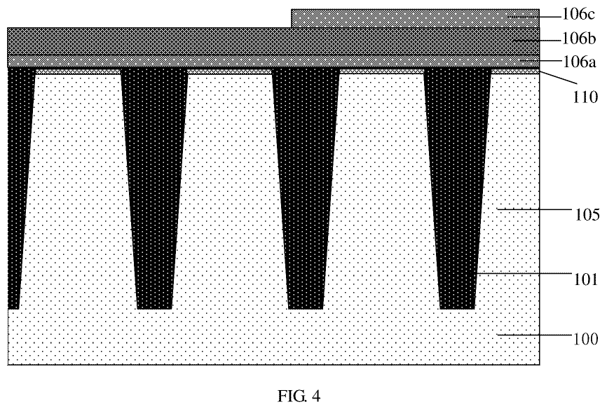

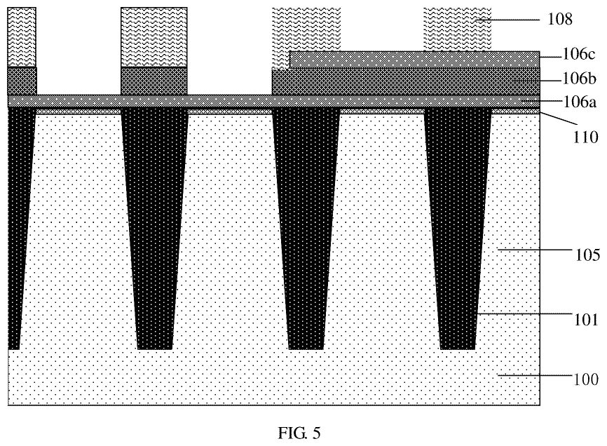

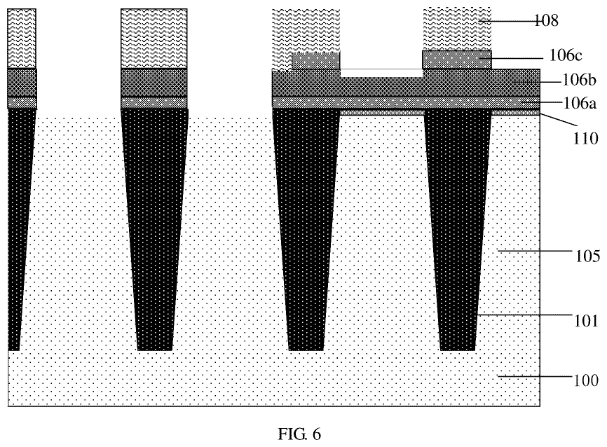

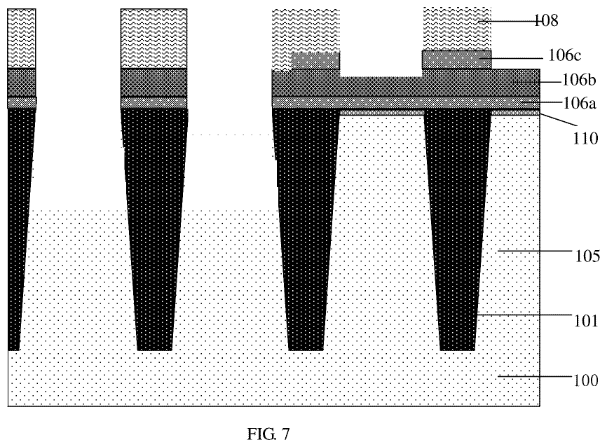

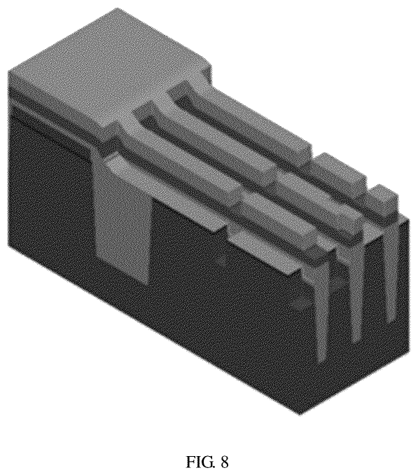

Disclosed is a fabrication method for a U-trench, including the following steps:
S1. providing a semiconductor silicon substrate 100 provided with a plurality of X-direction field oxygens 101 and a STI (shallow trench isolation) 102;
the semiconductor silicon substrate 100 includes a first area 103 and a second area 104 separated by the STI 102;
in the first area 103, the semiconductor silicon substrate 100 is isolated by a plurality of X-direction field oxygens 101 into a plurality of X-direction first active areas 105, and the plurality of X-direction field oxygens 101 and the plurality of X-direction first active areas 105 are arranged in parallel;
an X direction is a direction parallel to a length direction of the first active areas 105, and a Y direction is perpendicular to the X direction;
S2. opening the first area 103 to expose upper surfaces of the X-direction field oxygens 101 and upper surfaces of the first active areas 105 of the first area 103, as shown in FIG. 1;
S3. depositing a hard mask layer 106 on the first area 103, wherein the hard mask layer 106 includes a first silicon oxide layer 106a of mask, a second silicon nitride layer 106b of mask and a third silicon oxide layer 106c of mask that are sequentially overlapped from bottom to top, as shown in FIG. 2;
S4. coating a first photoresist on the hard mask layer 106, and then performing Y-direction opening lithography to form a Y-direction opening pattern; then performing Y-direction oxide etching to remove the third silicon oxide layer 106c of mask of the Y direction opening, and stopping the Y-direction oxide etching on a top surface of the second silicon nitride layer 106b of mask; and then removing the first photoresist, as shown in FIG. 3 and FIG. 4;
S5. coating a second photoresist 108 on a surface of the first area 103, and then define an X-direction opening pattern by lithography, wherein an X-direction opening corresponds to the corresponding first active area;
S6. according to the defined X-direction opening pattern, performing a first part of X-direction silicon nitride etching (U-trench X SIN ET), such that the second silicon nitride layer 106b of mask at an overlapping position of the X-direction opening pattern and the Y-direction opening pattern is removed, and the first part of X-direction silicon nitride etching stopped on the top surface of the first silicon oxide layer 106a of mask of the X-direction opening, the X-direction opening at a non-overlapping position of the X-direction opening pattern and the Y-direction opening pattern is covered with the first silicon oxide layer 106a of mask, the second silicon nitride layer 106b of mask and the third silicon oxide layer 106c of mask, as shown in FIG. 5;
S7. according to the defined X-direction opening pattern, performing a second part of X-direction oxide etching (U-trench X OX ET) for at least one time, such that the first silicon oxide layer 106a of mask at the overlapping position of the X-direction opening pattern and the Y-direction opening pattern is removed, and the second part of X-direction oxide etching stopped on the top surface of the semiconductor silicon substrate 100, the X-direction opening at the non-overlapping position of the X-direction opening pattern and the Y-direction opening pattern is covered with the first silicon oxide layer 106a of mask and the second silicon nitride layer 106b of mask, as shown in FIG. 6;
S8. according to the defined X-direction opening pattern, performing a third part of X-direction silicon etching (U-trench X SI ET), such that the U-trench is formed in the semiconductor silicon substrate at the overlapping position of the X-direction opening pattern and the Y-direction opening pattern, as shown in FIG. 7;
S9. sequentially removing the second silicon nitride layer 106b of mask and the first silicon oxide layer 106a of mask covered by the X-direction opening at the non-overlapping position of the X-direction opening pattern and the Y-direction opening pattern, as shown in FIG. 8; and
S10. performing a subsequent process.

Preferably, the X-direction field oxygens 101 are formed by using a shallow trench isolation process.

According to the fabrication method for the U-trench of the embodiment 1, process windows of the U-trench Y-direction opening hard mask etching, the U-trench X-direction opening hard mask etching and the U-trench area silicon etching do not affect each other, which increases the process tolerance. The second photoresist 108 retained on the field oxygens 103 in the X-direction lithography process of the U-trench will protect the hard mask (the first silicon oxide layer 106a, the second silicon nitride layer 106b of mask) on the field oxygens 103 of the Y-direction opening of the non-U-trench area without causing the loss of the hard mask on the field oxygens of the Y-direction opening of the non-U-trench area, which enlarges the process window of the U-trench. In a process of performing X-direction silicon etching (U-trench X SI ET) to form the U-trench in the semiconductor silicon substrate at the overlapping position of the X-direction opening pattern and the Y-direction opening pattern, silicon at the X-direction opening at the non-overlapping position of the X-direction opening pattern and the Y-direction opening pattern is protected by the first silicon oxide layer 106a of mask and the second silicon nitride layer 106b of mask. When the mask at the X-direction opening at the non-overlapping position of the X-direction opening pattern and the Y-direction opening pattern is removed, the first silicon oxide layer 106a is removed after the second silicon nitride layer 106b of mask is removed, which has no damage on the SIN hard mask on the field oxygens 103 and ensure the profile standard of the U-trench. In addition, the fabrication method for the U-trench requires less mask.

### Embodiment 2

Based on the fabrication method for the U-trench of the embodiment 1, in the step S1, a pad layer 109 is formed on an upper surface of the semiconductor silicon substrate 100; and the first active areas 105 are covered with the pad layer 109.

In the step S2, the pad layer 109 on the first area 103 is removed and the first area 103 is opened.

Preferably, the pad layer 109 is composed of a lower pad silicon oxide layer 110 and an upper silicon nitride layer;
in the step S2, the upper silicon nitride layer on the first active areas 105 of the first area 103 is removed and the lower pad silicon oxide layer 110 is retained, and the first area 103 is opened;
in the step S7, the second part of X-direction oxide etching is performed for at least one time according to the defined X-direction opening pattern, such that the first silicon oxide layer 106a of mask at the overlapping position of the X-direction opening pattern and the Y-direction opening pattern and the lower pad silicon oxide layer 110 are removed; and the second part of X-direction oxide etching is stopped on the top surface of the semiconductor silicon substrate 100, such that the X-direction opening at the non-overlapping position of the X-direction opening pattern and the Y-direction opening pattern is covered with the lower pad silicon oxide layer 110, the first silicon oxide layer 106a of mask and the second silicon nitride layer 106b of mask, and simultaneously the top of the second silicon nitride layer 106b of mask covered by the X-direction opening at the non-overlapping position of the X-direction opening pattern and the Y-direction opening pattern is removed by etching; and
in the step S9, the second silicon nitride layer 106b of mask, the first silicon oxide layer 106a of mask and the lower pad silicon oxide layer 110 covered by the X-direction opening at the non-overlapping position of the X-direction opening pattern and the Y-direction opening pattern are removed sequentially.

### Embodiment 3

Based on the fabrication method for the U-trench of the embodiment 1, in the step S4, the Y-direction oxide etching is high-selectivity etching with an OX/SIN selectivity of greater than 50:1, and stopped at the SIN; and the etching process is stable and controllable.

### Embodiment 4

Based on the fabrication method for the U-trench of the embodiment 1, in the step S6, the first part of X-direction silicon nitride etching is high-selectivity etching with a SIN/OX selectivity of greater than 50:1.

In the step S7, the second part of X-direction oxide etching is low-selectivity etching with an OX/SIN selectivity of less than 5:1, and the upper surface of the semiconductor silicon substrate in the U-trench area is exposed.

Based on the fabrication method for the U-trench of the embodiment 4, a second part of X-direction oxide etching (U-trench X OX ET) is of OX/SIN low selectivity etching, which can alleviate an OX taper profile, and facilitate the reduction of a Si sharp corner of the U-trench in a Si trench etching process.

### Embodiment 5

Based on the fabrication method for the U-trench of the embodiment 1, the U-trench is a semi-floating-gate trench of a semi-floating-gate transistor.

Preferably, the first area 103 is a formation area of a plurality of semi-floating-gate transistors; and in the first area 103, the plurality of semi-floating-gate transistors are arranged to form a storage array.

Preferably, each of the first active area 105 is provided with a first conductive type well, and the first conductive type well is formed in a surface area of a second conductive type well; and the U-trench passes through the first conductive type well, and a bottom surface of the U-trench enters the second conductive type well.

Preferably, the semi-floating-gate transistor is an N-type device, a first conductive type is N-type, and a second conductive type is P-type; or the semi-floating-gate transistor is a P-type device, a first conductive type is P-type, and a second conductive type is N-type.

The embodiments described above are only preferred embodiments of the present application and are not intended to limit the present application. The scope of protection of the application shall include any modifications, equivalent substitutions, improvements, etc. made within the spirit and principles of the present application.

What is claimed is:

1. A fabrication method for a U-trench, comprising the following steps:
S1: providing a semiconductor silicon substrate provided with a plurality of X-direction field oxygens and a shallow trench isolation, wherein
the semiconductor silicon substrate comprises a first area and a second area separated by the shallow trench isolation;
in the first area, the semiconductor silicon substrate is isolated by a plurality of X-direction field oxygens into a plurality of X-direction first active areas, and the plurality of X-direction field oxygens and the plurality of X-direction first active areas are arranged in parallel; and
an X direction is a direction parallel to a length direction of the first active areas, and a Y direction is perpendicular to the X direction;
S2: opening the first area to expose upper surfaces of the X-direction field oxygens and upper surfaces of the first active areas of the first area;
S3: depositing a hard mask layer on the first area, wherein the hard mask layer comprises a first silicon oxide layer of mask, a second silicon nitride layer of mask, and a third silicon oxide layer of mask that are sequentially overlapped from bottom to top;
S4: coating a first photoresist on the hard mask layer, and then performing Y-direction opening lithography to form a Y-direction opening pattern; then performing Y-direction oxide etching to remove the third silicon oxide layer of mask of the Y direction opening, and stopping the Y-direction oxide etching on a top surface of the second silicon nitride layer of mask; and then removing the first photoresist;
S5: coating a second photoresist on a surface of the first area, and then define an X-direction opening pattern by lithography, wherein an X-direction opening corresponds to the corresponding first active area;
S6: according to the defined X-direction opening pattern, performing a first part of X-direction silicon nitride etching, such that the second silicon nitride layer of mask at an overlapping position of the X-direction opening pattern and the Y-direction opening pattern is removed; and the first part of X-direction silicon nitride etching stopped on the top surface of the first silicon oxide layer of mask of the X-direction opening, such that the X-direction opening at a non-overlapping position of the X-direction opening pattern and the Y-direction opening pattern is covered with the first silicon oxide layer of mask, the second silicon nitride layer of mask and the third silicon oxide layer of mask;
S7: according to the defined X-direction opening pattern, performing a second part of X-direction oxide etching for at least one time, such that the first silicon oxide layer of mask at the overlapping position of the X-direction opening pattern and the Y-direction opening pattern is removed; and the second part of X-direction oxide etching stopped on a top surface of the semiconductor silicon substrate, the X-direction opening at the non-overlapping position of the X-direction opening pattern and the Y-direction opening pattern is covered with the first silicon oxide layer of mask and the second silicon nitride layer of mask;
S8: according to the defined X-direction opening pattern, performing a third part of X-direction silicon etching, such that the U-trench is formed in the semiconductor silicon substrate at the overlapping position of the X-direction opening pattern and the Y-direction opening pattern;
S9: sequentially removing the second silicon nitride layer of mask and the first silicon oxide layer of mask covered by the X-direction opening at the non-overlapping position of the X-direction opening pattern and the Y-direction opening pattern; and
S10: performing a subsequent process.

2. The fabrication method for the U-trench according to claim 1, wherein the X-direction field oxygens are formed by using a shallow trench isolation process.

3. The fabrication method for the U-trench according to claim 1, wherein
in the step S1, a pad layer is formed on an upper surface of the semiconductor silicon substrate; and the first active areas are covered with the pad layer; and
in the step S2, the pad layer on the first area is removed and the first area is opened.

4. The fabrication method for the U-trench according to claim 3, wherein
the pad layer is composed of a lower pad silicon oxide layer and an upper silicon nitride layer;
in the step S2, the upper silicon nitride layer on the first active areas of the first area is removed and the lower pad silicon oxide layer is retained, and the first area is opened;
in the step S7, the second part of X-direction oxide etching is performed for at least one time according to the defined X-direction opening pattern, such that the first silicon oxide layer of mask at the overlapping position of the X-direction opening pattern and the Y-direction opening pattern and the lower pad silicon oxide layer are removed; and the second part of X-direction oxide etching is stopped on the top surface of the semiconductor silicon substrate, such that the X-direction opening at the non-overlapping position of the X-direction opening pattern and the Y-direction opening pattern is covered with the lower pad silicon oxide layer, the first silicon oxide layer of mask and the second silicon nitride layer of mask; and
in the step S9, the second silicon nitride layer of mask, the first silicon oxide layer of mask and the lower pad silicon oxide layer covered by the X-direction opening at the non-overlapping position of the X-direction opening pattern and the Y-direction opening pattern are removed sequentially.

5. The fabrication method for the U-trench according to claim 1, wherein, in the step S4, the Y-direction oxide etching is high-selectivity etching with an OX/SIN selectivity of greater than 50:1.

6. The fabrication method for the U-trench according to claim 1, wherein
in the step S6, the first part of X-direction silicon nitride etching is high-selectivity etching with a SIN/OX selectivity of greater than 50:1; and
in the step S7, the second part of X-direction oxide etching is low-selectivity etching with an OX/SIN selectivity of less than 5:1, and the upper surface of the semiconductor silicon substrate in the U-trench area is exposed.

7. The fabrication method for the U-trench according to claim 1, wherein the U-trench is a semi-floating-gate trench of a semi-floating-gate transistor.

8. The fabrication method for the U-trench according to claim 7, wherein
the first area is a formation area of a plurality of semi-floating-gate transistors; and
in the first area, the plurality of semi-floating-gate transistors are arranged to form a storage array.

9. The fabrication method for the U-trench according to claim 7, wherein
each of the first active areas is provided with a first conductive type well, and the first conductive type well is formed in a surface area of a second conductive type well; and
the U-trench passes through the first conductive type well, and a bottom surface of the U-trench enters the second conductive type well.

10. The fabrication method for the U-trench according to claim 9, wherein
the semi-floating-gate transistor is an N-type device, a first conductive type is N-type, and a second conductive type is P-type; or
the semi-floating-gate transistor is a P-type device, a first conductive type is P-type, and a second conductive type is N-type.
